(19) United States
(12) Patent Application Publication
(10) Pub. No.: US 2014/0218223 A1
(43) Pub. Date: Aug. 7, 2014

(54) MULTIPLEXED SIGMA DELTA MODULATOR

(71) Applicant: Microsemi Corp. - Analog Mixed Signal Group, Ltd., Hod Hasharon (IL)

(72) Inventors: Yair DARSHAN, Petach Tikva (IL); Simon KAHN, Jerusalem (IL)

(73) Assignee: Microsemi Corp. - Analog Mixed Signal Group, Ltd., Hod Hasharon (IL)

(21) Appl. No.: 14/171,809

(22) Filed: Feb. 4, 2014

Related U.S. Application Data
(60) Provisional application No. 61/761,249, filed on Feb. 6, 2013.
(60) Provisional application No. 61/816,821, filed on Apr. 29, 2013.

(51) Int. Cl. H03M 3/00

(52) U.S. Cl. CPC H03M 3/39
USPC 341/143

(57) ABSTRACT

A multiplexed sigma delta modulator constituted of: a control circuitry; a multiplexer responsive to the control circuitry and arranged to receive a plurality of input signals; a comparing circuit, a first input of the comparing circuit coupled to the output of the multiplexer; an integrator, the input of the integrator coupled to the output of the comparing circuit; a latched comparing circuit, one input of the latched comparing circuit coupled to the output of the integrator; a plurality of storage elements, each associated with one of the plurality of inputs; and a feedback circuit arranged to feedback the output of the latched comparing circuit to the second input of the comparing circuit, wherein the control circuitry is further arranged to store the charge of an element of the integrator on the associated storage element when the associated signal is not passed by the multiplexer to the output of the multiplexer.

### TECHNICAL FIELD

The present invention relates to the field of analog to digital converters, and in particular to a multiplexed sigma-delta modulator utilized in such a converter.

### BACKGROUND OF THE INVENTION

Sigma delta analog to digital converters are typically constituted of a delta sigma modulator followed by a filter. A sigma delta modulator 10, as shown in FIG. 1, is typically implemented by: a differential amplifier 20; a latched comparator 30; a 1 bit digital to analog converter (DAC) 40; and an integrator 50, constituted of a differential amplifier 52; an input resistor 54 and integrating capacitor 56. The input voltage to be digitized, denoted VIN, is coupled to the non-inverting input of differential amplifier 20, and the output of differential amplifier 20 is coupled to a first end of input resistor 54 of integrator 50. A second end of input resistor 54 is coupled to the inverting input of differential amplifier 52 and to a first end of integrating capacitor 56. A second end of integrating capacitor 56 is commonly coupled to the output of differential amplifier 52 and to the non-inverting input of latched comparator 30. The non-inverting input of differential amplifier 52 is coupled to a common potential and the inverting input of comparator 30 is coupled to a threshold voltage, optionally being the common potential. The output of latched comparator 30 represents the bit stream output, and is coupled to the input of 1 bit DAC 40. The output of 1 bit DAC 40 is coupled to the inverting input of differential amplifier 20. 1 bit DAC 40 is a circuit arranged to alternately output a first and second reference value responsive to the input value. In an exemplary embodiment the second reference value is equal in value, and opposite in sign, to the first reference value. Latched comparator 30 is responsive to an external trigger signal (not shown), which is typically a clocking signal, to latch the output value until the following trigger signal is received.

In operation, sigma delta modulator 10 converts the mean of an analog voltage into the mean of an analog pulse frequency. A filter (not shown) counts the pulses over a pre-determined interval so that the pulse count divided by the interval gives digital representation of the mean analog voltage during the interval. This interval can be chosen to provide any desired resolution or accuracy and the circuitry is relatively inexpensive to implement. ΣΔ is the mathematical symbol for the summation of delta pulses. The negative feed-back loop to differential amplifier 20 ensures that the average value of the output of integrator 50 is equal to the input voltage VIN. As described above, 1 bit DAC 40 provides a pair of fixed reference voltages, responsive to the output of latched comparator 30, which reference voltages are alternately compared by differential amplifier 20 to VIN, thereby alternately charging and discharging integrating capacitor 56. In certain embodiments 1 bit DAC 40 may be implemented internal to latched comparator 30.

Sigma delta modulator 10 unfortunately does not react quickly to widely changing inputs, particularly due to the need for integrator 50 and the digital filter connected to the bit stream output (not shown) to reach steady state. Thus, sigma delta modulator 10 is not typically used for more than one input signal, where the values of the inputs may significantly differ, unless care is taken to ensure that sigma delta modulator 10 has completely settled before changing input, and where the resultant low throughput due to the inherent latency is sufficient to meet the application requirement.

U.S. Pat. No. 7,760,118 issued Jul. 20, 2010 to Rzehak, the entire contents of which is incorporated herein by reference, is addressed to a multiplexing aware sigma-delta analog to digital converter (ADC). A memory is adapted to hold the register content of the digital filter relating to the first input signal while the second input signal is processed in the digital filter, and a controller is arranged to retrieve the register contents from the memory when processing of the first input signal in the digital filter is resumed. Such a mechanism requires a large memory and may add to cost, and in some cases doesn't resolve the latency issue caused by the time response and time delay of the integrator due to large voltage difference between the different inputs multiplexed to the input of the sigma delta modulator.

### SUMMARY OF THE INVENTION

Accordingly, it is a principal object of the present invention to overcome at least some of the disadvantages of the prior art. This is provided in certain embodiments by providing at least one storage element for the sigma delta modulator associated with each input. The storage element acts as a memory to retain the integrator charge value when any of the other inputs are selected. The integrator charge value associated with the input is utilized in combination with its associated input, and thus convergence time to steady state when switching from one input to another is reduced. The storage elements are typically implemented as capacitors.

In one particular embodiment a plurality of integrator capacitors are provided as storage elements, each associated with a particular input. In another embodiment the charge on the integrator capacitor is stored on the associated storage element capacitor, and restored as required.

In one embodiment, a multiplexed sigma delta modulator is enabled, the multiplexed sigma delta modulator comprising: a control circuitry; a multiplexer responsive to the control circuitry and arranged to receive a plurality of input signals; a differential amplifier, a first input of the differential amplifier coupled to the output of the multiplexer; an integrator, the input of the integrator coupled to the output of the differential amplifier; a latched comparing circuit, one input of the latched comparing circuit coupled to the output of the integrator; a plurality of storage elements, each associated with one of the plurality of inputs; and a feedback circuit arranged to feedback the output of the latched comparing circuit to the second input of the differential amplifier, wherein the control circuitry is further arranged to store the charge of an element of the integrator on the associated storage element when the associated signal is not passed by the multiplexer to the output of the multiplexer.

In one further embodiment the feedback circuit comprises a 1 bit digital to analog converter, the output of the latched comparing circuit coupled to the input of the 1 bit digital to analog converter, the output of the 1 bit digital to analog converter coupled to the input of the differential amplifier. In another further embodiment the integrator comprises a current source arranged to provide current level whose value and sign are responsive to the output of the comparing circuitry.

In one further embodiment the element of the integrator comprises the associated storage element when the associated signal is passed by the multiplexer to the output of the multiplexer. In another further embodiment the control circuitry is further arranged to couple the associated storage element to act as the integrator element when the associated signal is passed by the multiplexer to the output of the multiplexer responsive to the control circuitry. In yet another embodiment the multiplexed sigma delta modulator further comprises a pair of buffers associated with each of the storage element, a first of the buffers arranged to store the charge of the integrator element onto the associated storage element responsive to the control circuitry, and a second of the buffers arranged to load the charge of the associated storage element onto the integrator element responsive to the control circuitry.

In another embodiment a sigma delta modulator comprising an integrator, the method comprising: selecting a first one of a plurality of input signals; comparing the selected first input signal with a feedback signal to provide a difference signal; integrating the difference signal over time via the integrator; comparing the integrated comparison with a threshold value; latching the compared value, wherein the feedback signal is responsive to the latched compared value; storing the charge of an element of the integrator on a storage element associated with the first input signal; selecting a second of the plurality on input signals; loading the integrator element with a stored charge associated with the selected second input signal; and comparing the selected second input signal with the feedback signal to provide the difference signal.

In one further embodiment the feedback signal is fed through a 1 bit digital to analog converter so as to alternately present one of two predetermined values for the comparing with the respective selected input signal. In another further embodiment the first input signal is selected, the integrator element is the storage element associated with the first input signal, and when the second input signal is selected, the integrator element is the storage element associated with the second input signal. In yet another further embodiment the charge of the integrator element is stored to the storage element associated with the respective input contemporaneously with deselecting the respective input, and is loaded to the integrator element from the storage element associated with the respective input prior contemporaneously with selecting the respective input.

Additional features and advantages of the invention will become apparent from the following drawings and description.

### BRIEF DESCRIPTION OF THE DRAWINGS

For a better understanding of the invention and to show how the same may be carried into effect, reference will now be made, purely by way of example, to the accompanying drawings in which like numerals designate corresponding elements or sections throughout.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 illustrates a high level schematic diagram of a sigma delta modulator of the prior art;

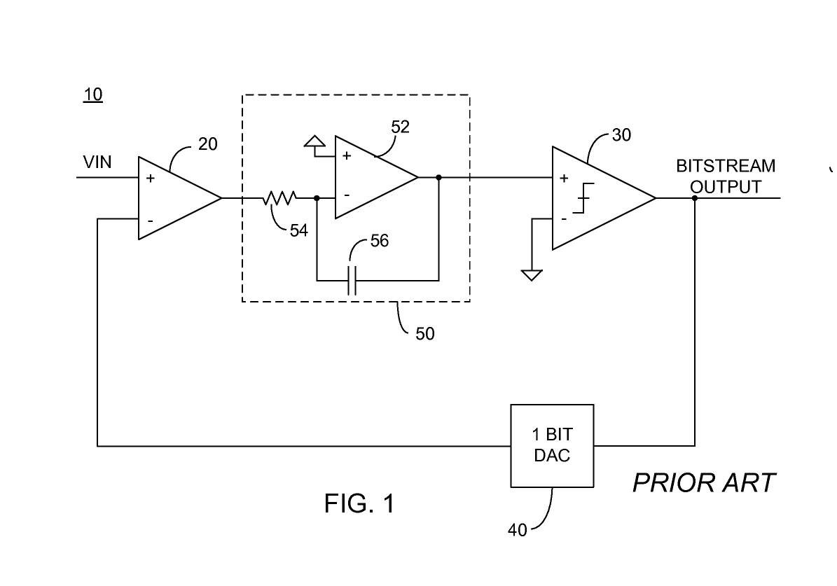

FIG. 2 illustrates a high level schematic diagram of an exemplary multiplexed sigma delta modulator wherein for each selectable input a particular integrator storage capacitor is provided;

FIG. 3 illustrates a high level schematic diagram of an exemplary multiplexed sigma delta modulator wherein for each selectable input a storage element is provided and wherein the integrator storage element is loaded with a value from the associated storage element when the input is selected; and

FIG. 4 illustrates a high level flow chart of a method of multiplexing a sigma delta modulator, according to certain embodiments.

### DETAILED DESCRIPTION OF PREFERRED EMBODIMENTS

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

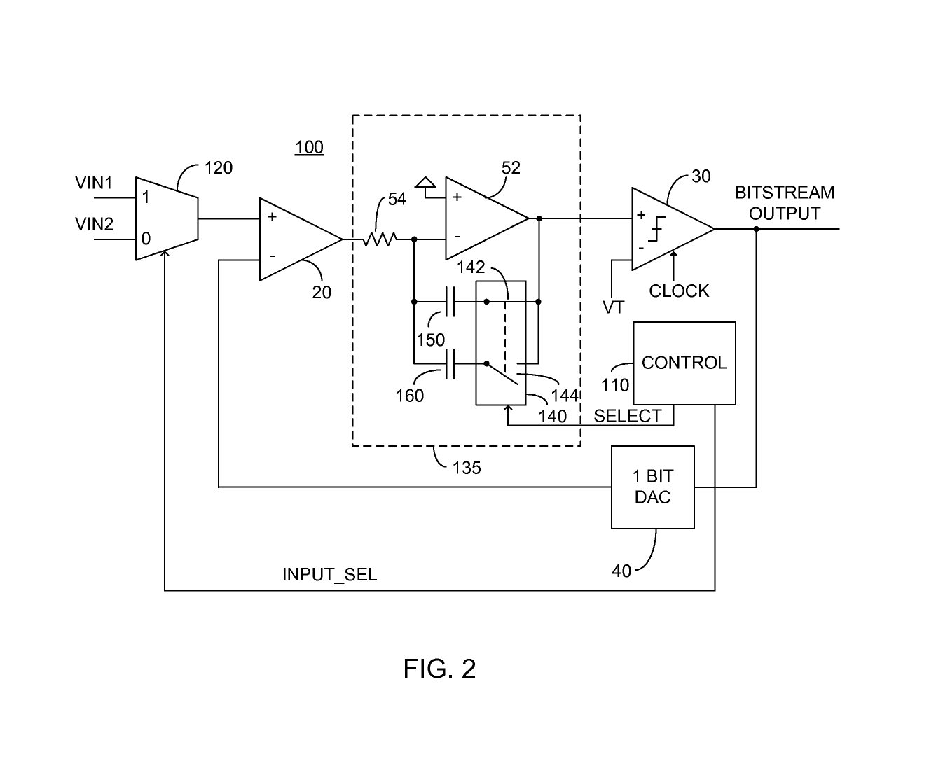

FIG. 2 illustrates a high level schematic diagram of an exemplary multiplexed sigma delta modulator 100 comprising: a control circuitry 110; a multiplexer 120; a differential amplifier 20; a switchable integrator 135; a latched comparator 30; a 1 bit DAC 40; and a control circuitry 180. Switchable integrator 135 comprises: a differential amplifier 52; an input resistor 54; a switching unit 140 comprising a first electronically controlled switch 142 and a second electronically controlled switch 144; a first integrator capacitor 150; and a second integrator capacitor 160.

A first input, denoted VIN1, is coupled to a first input of multiplexer 120. A second input, denoted VIN2, is coupled to a second input of multiplexer 120. The output of multiplexer 120 is coupled to the non-inverting input of differential amplifier 20, and the output of differential amplifier 20 is coupled to a first end of input resistor 54. A second end of first input resistor 54 is coupled to the inverting input of differential amplifier 52, a first end of first integrator capacitor 150 and a first end of second integrator capacitor 160. A second end of first integrator capacitor 150 is switchably coupled to the output of differential amplifier 52 via first electronically controlled switch 142 and a second end of second integrator capacitor 160 is switchably coupled to the output of differential amplifier 52 via second electronically controlled switch 144. A respective output of control circuitry 110 is coupled to a control input of switching unit 140 so as to control the operation of each of first electronically controlled switch 142 and second electronically controlled switch 144, the signal output from control circuitry 110 denoted SELECT. The output of differential amplifier 52 is further coupled to the non-inverting input of latched comparator 30. The inverting input of latched comparator 30 is coupled to a reference voltage, denoted VT, which may be in some implementations a common potential. The output of latched comparator 30, which represents the bit stream output, typically denoted BO, is coupled to the input of 1 bit DAC 40. The output of 1 bit DAC 40 is coupled to the inverting input of differential amplifier 20. The non-inverting input of differential amplifier 52 is coupled to a predetermined reference point, illustrated without limitation as the common potential. A respective output of control circuitry 110 is coupled to the control input of multiplexer 120, the signal denoted INPUT_SEL. Latched comparator 30 further receives a clock input signal, denoted CLOCK, and is responsive thereto to latch the output of comparator 30 between respective triggers of CLOCK.

In operation, control circuitry 110 is arranged to select first input signal VIN1 by setting signal INPUT_SEL to a first predetermined value, illustrated herein as 1, and sets multiplexer 120 to pass input signal VIN1 via the output of multiplexer 120 to differential amplifier 20. Differential amplifier 20 compares the received input from multiplexer 120 to the output of 1 bit DAC 40, and feeds the difference as a difference signal to switchable integrator 135. Control circuitry 110, contemporaneously, or at a predetermined interval in advance of setting signal INPUT_SEL further sets signal SELECT so as to close first electronically controlled switch 142 and open second electronically controlled switch 144. First capacitor 150 is thus coupled between the inverting input and the output of differential amplifier 52, thereby acting as the integrator capacitor of switchable integrator 135. The charge on second capacitor 160 is maintained as long as second electronically controlled switch 144 is open; second capacitor 160 thus acting as a storage element. As described above in relation to sigma delta modulator 10, the bit stream output of latched comparator 30 comprises a digitized version of input signal VIN1 over time, responsive to 1 bit DAC 40, differential amplifier 20 and the integrator formed by differential amplifier 52 and first capacitor 150.

VIN1 and VIN2 change slowly in relation to the function of the clock input to latched comparator 30, which is typically clocked at a frequency much greater than the input frequency, known as oversampling.

Control circuitry 110, responsive to an external signal, or after a predetermined period of time, which is optionally responsive to a plurality of periods of CLOCK, is further arranged to select second input signal VIN2 by setting signal INPUT_SEL to a second predetermined value, illustrated herein as 0, and sets multiplexer 120 to pass second input signal VIN2 to the output, where it is coupled to the non-inverting input of differential amplifier 20. Differential amplifier 20 compares the received input from multiplexer 120 to the output of 1 bit DAC 40, and feeds the difference to switchable integrator 135. Control circuitry 110, contemporaneously, or at a predetermined interval in advance of setting signal INPUT_SEL further sets signal SELECT so as to open first electronically controlled switch 142 and close second electronically controlled switch 144. Second capacitor 160 is thus coupled between the inverting input and the output of differential amplifier 52 thereby acting as the integrator capacitor of switchable integrator 135. The charge on first capacitor 150 is maintained as long as first electronically controlled switch 142 is open; first capacitor 150 thus acting as a storage element. As described above in relation to sigma delta modulator 10, the bit stream output of latched comparator 30 comprises a digitized version of input signal VIN2 over time, responsive to 1 bit DAC 40, differential amplifier 20 and the integrator formed by differential amplifier 52 and second capacitor 160.

Control circuitry 110, responsive to an external signal, or after a predetermined period of time, is further arranged to again select first input signal VIN1 by setting signal INPUT_SEL to the first predetermined value, illustrated herein as 1, as described above, and contemporaneously setting signal SELECT to set first capacitor 150 as the integrator capacitor of switchable integrator 135. Advantageously, the charge on second capacitor 160 is stored thereon, and the value on first capacitor 150, representative of the previous instance of multiplexing first input signal VIN1, is utilized in the integrator. Preferably first and second electronically controlled switches 142, 144 are arranged to switch alternately with a dead time in between, responsive to input SELECT, to avoid passing charge from first capacitor 150 to second capacitor 160 during the switching activity.

Thus, when input signal VIN1 is selected and passed by multiplexer 120, first capacitor 150 is utilized in the switchable integrator 135, and the last value stored thereon is thereby utilized by sigma delta modulator 100. In particular, switchable integrator 135 thus continues integration where it left off when input signal VIN1 was last selected.

Similarly, when input signal VIN2 is selected and passed by multiplexer 120, second capacitor 160 is utilized in switchable integrator 135, and the last value stored thereon is utilized by sigma delta modulator 100. In particular, switchable integrator 135 thus continues integration where it left off when input signal VIN2 was last selected. Advantageously, in one embodiment first capacitor 150 and second capacitor 160 exhibit different capacitances thereby allowing for a wide range of input signals without significantly affecting the speed of switchable integrator 135.

Multiplexed sigma delta modulator 100 is illustrated above with 2 inputs, each having an associated integrator capacitor; however this is not meant to be limiting in any way. Any number of inputs may be provided, each with its associated integrator capacitor without exceeding the scope. Thus, when the associated input is selected, the respective capacitor associated therewith serves as the integrator element, and the other capacitor, or capacitors, serves as storage elements.

Multiplexed sigma delta modulator 100 is illustrated with the storage element implemented as a capacitor, however this is not meant to be limiting in any way, and an inductor may be utilized as the storage element without exceeding the scope.

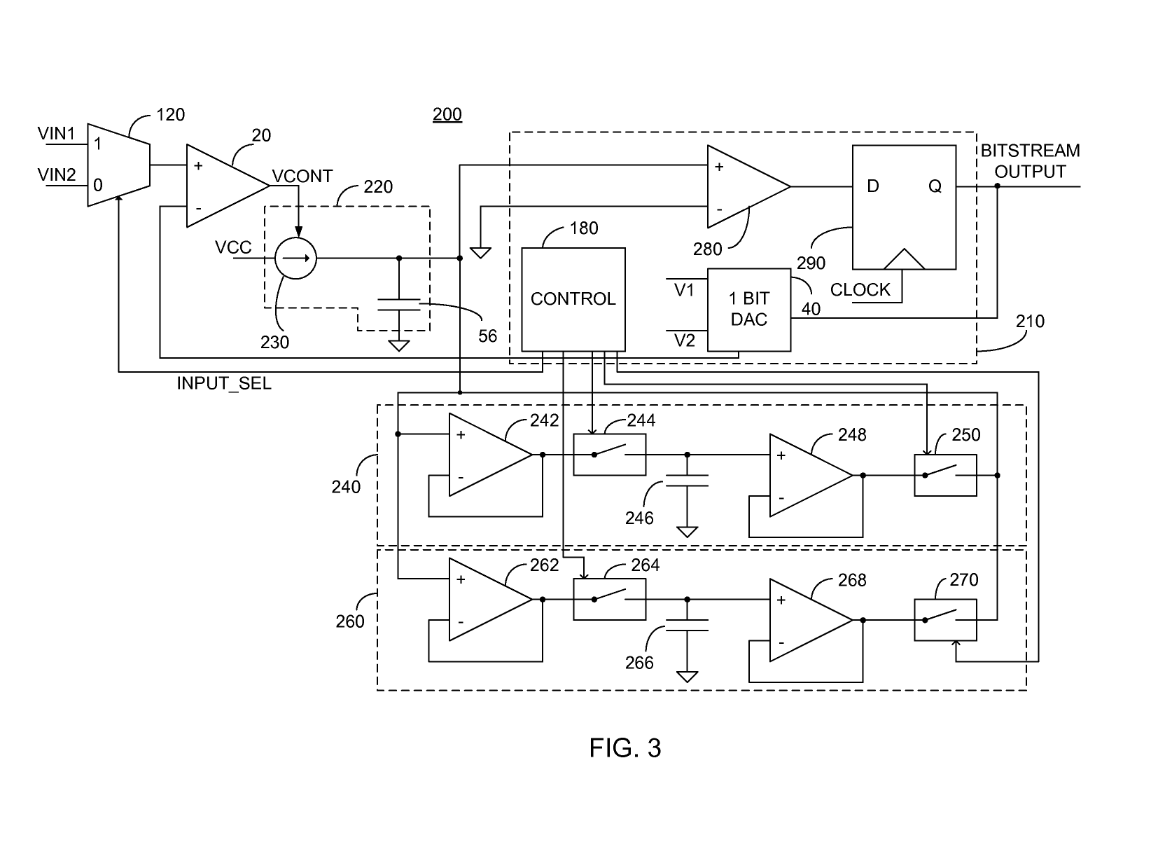

FIG. 3 illustrates a high level schematic diagram of a multiplexed sigma delta modulator 200 wherein for each selectable input a storage element is provided and wherein the integrator storage element is loaded with a value from the associated storage element when the input is selected. In particular, multiplexed sigma delta modulator 200 comprises control circuitry 180; a multiplexer 120; a differential amplifier 20 ; an integrator 220 comprising a controllable current source 230 and an integrator capacitor 56; a first additional storage element 240; a second additional storage element 260; a 1 bit DAC 40; a comparing circuit 280 and a latch 290. First additional storage element 240 comprises: an input buffer 242; a first electronically controlled switch 244; a capacitor 246; an output buffer 248; and a second electronically controlled switch 250. Second additional storage element 260 comprises: an input buffer 262; a first electronically controlled switch 264; a capacitor 266; an output buffer 268; and a second electronically controlled switch 270. 1 bit DAC 40 is shown with inputs V1 and V2 as described above in relation to the first and second reference values. Latch 290 is illustrated as a D flip flop without limitation.

A first input, denoted VIN1, is coupled to the first input of multiplexer 120. A second input, denoted VIN2, is coupled to the second input of multiplexer 120. The output of multiplexer 120 is coupled to the non-inverting input of differential amplifier 20. The output of differential amplifier 20, denoted VCONT, representing a difference signal, is coupled to the control input of controllable current source 230 of integrator 220. A first end of current source 230 is coupled to a source of electric potential, denoted VCC, and the second end of controllable current source 230 is coupled to a first end of integrator capacitor 56, to the non-inverting input of comparing circuit 280, to the non-inverting input of each of input buffers 242 and 262 and to the output terminal of each of second electronically controlled switches 250, 270. A second end of integrator capacitor 56 is coupled to a common potential.

The output of comparator 280 is coupled to the input of latch 290. A clock signal, of a frequency greater than the maximum frequency of VIN, denoted CLOCK, is coupled to the clock input of latch 290. The Q output of latch 290 represents the bit stream output, and is coupled to the input of 1 bit DAC 40.

The output of 1 bit DAC 40 is coupled to the inverting input of differential amplifier 20. 1 bit DAC 40 is illustrated with inputs V1 and V2, which represent the first and second references as described above. Thus, the output of 1 bit DAC 40 is alternately coupled to one of V1 and V2 so as to ensure 1 bit digital to analog accurate conversion by fixed reference voltages for differential amplifier 20. In one embodiment 1 bit DAC 40 is incorporated within latching circuit 290 and is thus not required. In particular, in the event that latching circuit 290 is set to output one of 2 fixed reference voltages depending on its output state, the functionality of 1 bit DAC 40 is incorporated therein.

The control inputs of multiplexer 120, first electronically controlled switch 244, second electronically controlled switch 250, first electronically controlled switch 264 and second electronically controlled switch 270 are coupled to respective outputs of control unit 180. In particular, the control input of multiplexer 120 carries signal INPUT_SEL.

The inverting input of each of input buffers 242, 262 and output buffers 248, 268 are coupled to the respective outputs thereof. The output of input buffer 242 of first storage element 240 is coupled to the input lead of first electronically controlled switch 244, and the output lead of first electronically controlled switch 244 is coupled to a first end of capacitor 246 and to the non-inverting input of output buffer 248. The second end of capacitor 246 is coupled to the common potential. The output of output buffer 248 is coupled to the input lead of second electronically controlled switch 250.

The output of input buffer 262 of second storage element 260 is coupled to the input lead of first electronically controlled switch 264, and the output lead of first electronically controlled switch 264 is coupled to a first end of capacitor 266 and to the non-inverting input of output buffer 268. The second end of capacitor 266 is coupled to the common potential. The output of output buffer 268 is coupled to the input lead of second electronically controlled switch 270.

In operation, control unit 180 is arranged to select first input signal VIN1 by setting signal INPUT_SEL to a first predetermined value, illustrated herein as 1, and set multiplexer 120 to pass input signal VIN1 to the output, where it is coupled to the non-inverting input of differential amplifier 20. Just prior to, or contemporaneously with, the switching of multiplexer 120 to pass input signal VIN1 to the output, control unit 180 closes second electronically controlled switch 250 momentarily, and integrator capacitor 56 is charged to the value stored on capacitor 246 of first additional storage element 240 responsive to output buffer 248. First electronically controlled switch 244 is maintained open. Integrator capacitor 56 is thus pre-charged to the value stored on capacitor 246 of first additional storage element 240.

Controllable current source 230 is arranged to output a current whose value is responsive to the voltage level of signal VCONT. In one embodiment controllable current source 230 is arranged to output both positive and negative values responsive to the positive and negative values of signal VCONT. Integrator capacitor 56 is alternately charged and discharged responsive to controllable current source 230, and the charge thereon thus represents an integration over time of the output of controllable current source 230.

As described above in relation to sigma delta modulator 10, the bit stream output of latch 290 comprises a digitized version of input signal VIN1 over time, responsive to the feedback loop comprising differential amplifier 20 and integrator 220. As described above, 1 bit DAC 40 is arranged to alternate its output between two predetermined values, V1 and V2, responsive to the output of latch 290. Responsive to the alternating values of 1 bit DAC 40 and the output voltage of multiplexer 120, output CONT of differential amplifier 20 controls controllable current source 230 to alternately output currents I1, I2, thereby charging and discharging integrator capacitor 56. The charge across integrator capacitor 56, particularly the voltage there across, is compared via comparing circuit 280 with a threshold voltage, described above as VT, and herein illustrated as the common potential. Responsive to CLOCK the output of comparing circuit 280 is sampled and appears at the output of latch 290 as the bitstream output.

Control circuitry 180, responsive to an external signal, or after a predetermined period of time, is further arranged to select second input signal VIN2 by setting signal INPUT_SEL to a second predetermined value, illustrated herein as 0, and sets multiplexer 120 to pass second input signal VIN2 to the output, where it is coupled to the non-inverting input of differential amplifier 20. Prior to, or contemporaneously with, switching multiplexer 120 from VIN1 to VIN2, control circuitry 180 further momentarily closes first electronically controlled switch 244 of first additional storage element 240, while maintaining second electronically controlled switch 250 open, and responsive to input buffer 242, capacitor 246 is charged to store the value of the charge stored on integrator capacitor 56. First electronically controlled switch 244 is then opened so as to isolate and store the charge on capacitor 246.

Just prior to, or contemporaneously with, the switching of multiplexer 120 to pass input signal VIN2 to the output, and preferably after first electronically controlled switch 244 is opened so as to isolate and store the charge on capacitor 246, first control circuitry 210 closes second electronically controlled switch 270 of second additional storage element 260 momentarily, and integrator capacitor 56 is charged to the value stored on capacitor 266 of second additional storage element 260 responsive to output buffer 268. First electronically controlled switch 264 is maintained open. Integrator capacitor 56 is thus pre-charged to the value stored on capacitor 266 of second storage element 260.

As described above, the bit stream output of latch 30 comprises a digitized version of input signal VIN2 over time, responsive to the feedback loop, comprising differential amplifier 20 and integrator 220. Advantageously, the value rapidly settles since integrator 56 is pre-charged to the last value associated with VIN2 responsive to second additional storage element 260.

Multiplexed sigma delta modulator 200 is illustrated above with 2 inputs, each having an associated integrator capacitor; however this is not meant to be limiting in any way. Any number of inputs may be provided, each with its associated storage element without exceeding the scope. Each of first and second storage elements 240, 260 are illustrated with the storage element implemented as a capacitor, however this is not meant to be limiting in any way, and an inductor may be utilized as the storage element without exceeding the scope. Integrator 220 may similarly be implemented with an inductor without exceeding the scope.

The above has been described in an embodiment wherein buffers and associated electronically controlled switches are separately implemented, however this is not meant to be limiting in any way. For example, buffers 242, 262 may be implemented with an enable input, thus replacing the functionality of electronically controlled switches 244, 264 without exceeding the scope. Similarly, buffers 248, 268 may be implemented with an enable input, thus replacing the functionality of electronically controlled switches 250, 270 without exceeding the scope.

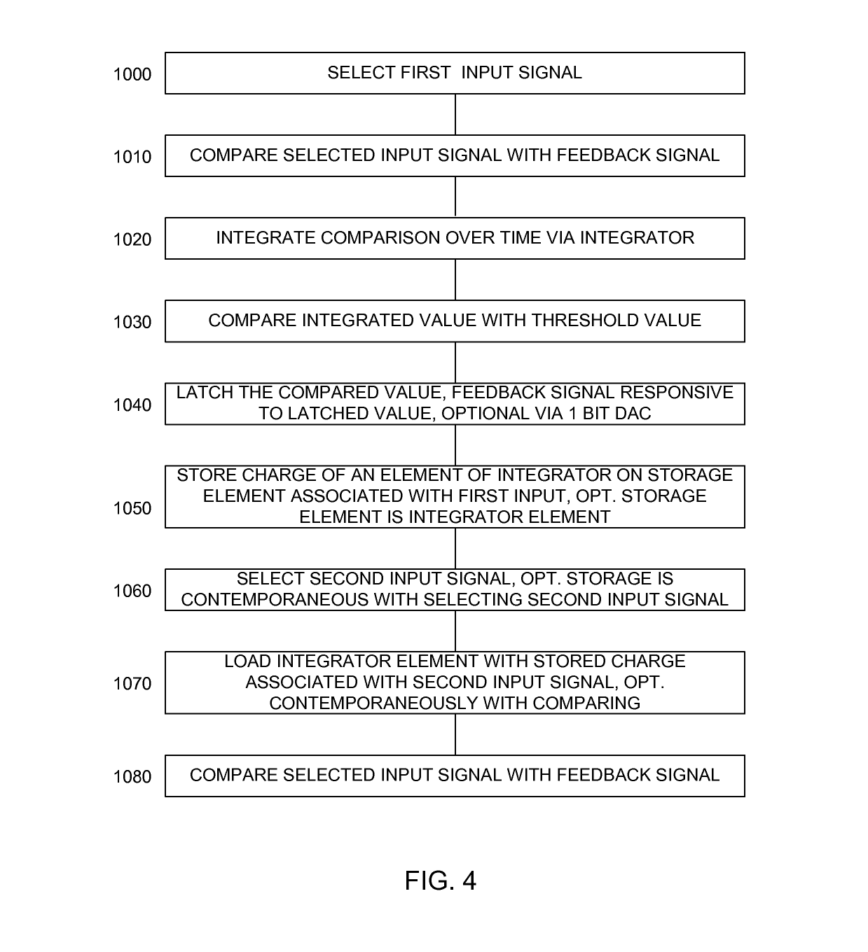

FIG. 4 illustrates a high level flow chart of a method of multiplexing a sigma delta modulator comprising an integrator, according to certain embodiments. In stage 1000 a first input signal of a plurality of input signals is selected. In stage 1010 the selected first input signal is compared with a feedback signal to provide a difference signal. In stage 1020 the result of the comparison is integrated over time in an integrator.

In stage 1030, the integrated value is compared with a threshold, such as threshold VT of sigma delta modulator 100. In stage 1040, the compared value of stage 1030 is latched, and the feedback signal of stage 1010 is responsive to the latched value. In one embodiment, the latched value is fed through a 1 bit DAC prior to use in stage 1010 so as to ensure that it varies cleanly between 2 predetermined values.

In stage 1050, the charge of an element of the integrator of stage 1020 is stored in a storage element associated with the selected first input of stage 1000. Optionally, as described in relation to signal delta modulator 100, the storage element is utilized as the integrator element when the first input signal is selected.

In stage 1060 the second input signal is selected. Optionally, the storage of stage 1050 is done contemporaneously with stage 1060. The term contemporaneous is meant to include at the same time, just prior to, or just after, without exceeding the scope, with the only limitation being that the value on the integrator of stage 1020 due to the selected first signal not be impacted yet by the selection of the second input signal. In one particular embodiment, as described above in relation to sigma delta modulator 200, just prior to switching multiplexer 110 to the second input signal, the charge on the integrator element is stored via the associated storage buffer.

In stage 1070, the integrator element is loaded with the stored charge associated with the selected input signal of stage 1060. Optionally, this is performed contemporaneously with the selection, and preferably the timing is such so as not to impact the storing of stage 1050. The term contemporaneous is meant to include at the same time, just prior to, or just after, without exceeding the scope, with the only limitation being that the value on the integrator of stage 1020 by successfully stored without impact, and that the value be loaded prior to the operation of stage 1080. In one particular embodiment, as described above in relation to sigma delta modulator 200, just prior to switching multiplexer 110 to the second input signal, the integrator element is loaded with the chard stored on the associated storage element via a buffer.

In stage 1080, the selected input signal is compared with the feedback signal to again output the difference signal as described above. Thus the sigma delta modulator integrator element is preloaded with the value associated with the input prior to performing comparison therewith. Such a multiplexed sigma delta modulator settles quickly after changes between widely varying inputs.

The above embodiments have been described in relation to a first order sigma delta modulator, for simplicity, however this is not meant to be limiting in any way, and the principles described herein are equally applicable to higher order sigma delta modulators without exceeding the scope.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

Unless otherwise defined, all technical and scientific terms used herein have the same meanings as are commonly understood by one of ordinary skill in the art to which this invention belongs. Although methods similar or equivalent to those described herein can be used in the practice or testing of the present invention, suitable methods are described herein.

All publications, patent applications, patents, and other references mentioned herein are incorporated by reference in their entirety. In case of conflict, the patent specification, including definitions, will prevail. In addition, the materials, methods, and examples are illustrative only and not intended to be limiting.

It will be appreciated by persons skilled in the art that the present invention is not limited to what has been particularly shown and described herein above. Rather the scope of the present invention is defined by the appended claims and includes both combinations and sub-combinations of the various features described hereinabove as well as variations and modifications thereof which would occur to persons skilled in the art upon reading the foregoing description and which are not in the prior art.

1. A multiplexed sigma delta modulator comprising:
a control circuitry;
a multiplexer responsive to said control circuitry and arranged to receive a plurality of input signals;
a differential amplifier, a first input of said differential amplifier coupled to the output of said multiplexer;
an integrator, the input of said integrator coupled to the output of said differential amplifier;
a latched comparing circuit, one input of said latched comparing circuit coupled to the output of said integrator;
a plurality of storage elements, each associated with one of the plurality of inputs; and
a feedback circuit arranged to feedback the output of said latched comparing circuit to the second input of said differential amplifier,
wherein said control circuitry is further arranged to store the charge of an element of the integrator on the associated storage element when the associated signal is not passed by said multiplexer to the output of said multiplexer.

2. The multiplexed sigma delta modulator of claim 1, wherein said feedback circuit comprises a 1 bit digital to analog converter, the output of said latched comparing circuit coupled to the input of said 1 bit digital to analog converter, the output of said 1 bit digital to analog converter coupled to the input of said differential amplifier.

3. The multiplexed sigma delta modulator of claim 1, wherein said integrator comprises a current source arranged to provide current level whose value and sign are responsive to the output of said comparing circuitry.

4. The multiplexed sigma delta modulator according to claim 1, wherein said element of the integrator comprises the associated storage element when the associated signal is passed by said multiplexer to the output of said multiplexer.

5. The multiplexed sigma delta modulator according to claim 1, wherein said control circuitry is further arranged to couple the associated storage element to act as the integrator element when the associated signal is passed by said multiplexer to the output of said multiplexer responsive to said control circuitry.

6. The multiplexed sigma delta modulator according to claim 1, wherein the multiplexed sigma delta modulator further comprises a pair of buffers associated with each of said storage element, a first of said buffers arranged to store the charge of said integrator element onto the associated storage element responsive to the control circuitry, and a second of said buffers arranged to load the charge of said associated storage element onto said integrator element responsive to the control circuitry.

7. A method of multiplexing a sigma delta modulator comprising an integrator, the method comprising:
selecting a first one of a plurality of input signals;
comparing said selected first input signal with a feedback signal to provide a difference signal;
integrating said difference signal over time via the integrator;
comparing said integrated comparison with a threshold value;
latching said compared value, wherein said feedback signal is responsive to said latched compared value;
storing the charge of an element of the integrator on a storage element associated with the first input signal;
selecting a second of said plurality on input signals;
loading the integrator element with a stored charge associated with the selected second input signal; and
comparing said selected second input signal with the feedback signal to provide the difference signal.

8. The method according to claim 7, wherein said feedback signal is fed through a 1 bit digital to analog converter so as to alternately present one of two predetermined values for said comparing with said respective selected input signal.

9. The method according to claim 7, wherein when said first input signal is selected, said integrator element is said storage element associated with the first input signal, and when said second input signal is selected, said integrator element is said storage element associated with the second input signal.

10. The method according to claim 7, wherein the charge of the integrator element is stored to said storage element associated with the respective input contemporaneously with deselecting said respective input, and is loaded to the integrator element from said storage element associated with the respective input prior contemporaneously with selecting said respective input.

11. A multiplexed sigma delta modulator comprising:
a control circuitry;
a multiplexer responsive to said control circuitry and arranged to receive a plurality of input signals;
a differential amplifier, a first input of said differential amplifier coupled to the output of said multiplexer;
a means for integrating, the input of said means for integrating coupled to the output of said differential amplifier;
a latched comparing circuit, one input of said latched comparing circuit coupled to the output of said means for integrating;
a plurality of storage elements, each associated with one of the plurality of inputs; and
a feedback circuit arranged to feedback the output of said latched comparing circuit to the second input of said differential amplifier,
wherein said control circuitry is further arranged to store the charge of an element of the means for integrating on the associated storage element when the associated signal is not passed by said multiplexer to the output of said multiplexer.

12. The multiplexed sigma delta modulator of claim 11, wherein said feedback circuit comprises a 1 bit digital to analog converter, the output of said latched comparing circuit coupled to the input of said 1 bit digital to analog converter, the output of said 1 bit digital to analog converter coupled to the input of said differential amplifier.

13. The multiplexed sigma delta modulator of claim 11, wherein said means for integrating comprises a current source arranged to provide current level whose value and sign are responsive to the output of said comparing circuitry.

14. The multiplexed sigma delta modulator according to claim 11, wherein said element of the means for integrating comprises the associated storage element when the associated signal is passed by said multiplexer to the output of said multiplexer.

15. The multiplexed sigma delta modulator according to claim 11, wherein said control circuitry is further arranged to couple the associated storage element to act as the means for integrating element when the associated signal is passed by said multiplexer to the output of said multiplexer responsive to said control circuitry.

16. The multiplexed sigma delta modulator according to claim 11, wherein the multiplexed sigma delta modulator further comprises a pair of buffers associated with each of said storage element, a first of said buffers arranged to store the charge of said means for integrating element onto the associated storage element responsive to the control circuitry, and a second of said buffers arranged to load the charge of said associated storage element onto said means for integrating element responsive to the control circuitry.
